(19) United States
(12) Patent Application Publication
(10) Pub. No.: US 2017/0149424 A1
(43) Pub. Date: May 25, 2017

(54) Ultra Low Power Reduced Coupling Clocked Comparator

(71) Applicant: Texas Instruments Incorporated, Dallas, TX (US)

(72) Inventors: Rajat Chauhan, Bangalore (IN); Keith Kunz, Bryan, TX (US)

(21) Appl. No.: 14/951,877

(22) Filed: Nov. 25, 2015

(51) Int. Cl. H03K 5/24

(52) U.S. Cl. CPC H03K 5/249

(57) ABSTRACT

A comparator circuit comprising a first node operable to receive a voltage during a precharge phase and a second node operable to receive the voltage during the precharge phase. The comparator circuit also comprises a first selectable current path, comprising a first input transistor and a first programmable resistor, coupled to the first node and for selectively discharging the first node, and a second selectable current path, comprising a second input transistor and a second programmable resistor, coupled to the second node and for selectively discharging the second node, in complementary operation with respect to the first selectable current path. The comparator circuit also comprises circuitry for adjusting resistance of the first programmable resistor and the second programmable resistor in response to an offset between the first input transistor and the second input transistor.

### CROSS-REFERENCES TO RELATED APPLICATIONS

Not Applicable.

### STATEMENT REGARDING FEDERALLY SPONSORED RESEARCH OR DEVELOPMENT

Not Applicable.

### BACKGROUND OF THE INVENTION

The preferred embodiments relate to clocked comparators, which are sometimes also referred to as sense amp flip flops, depending on application.

A clocked comparator (or sense amp flip flop) receives an input signal, a reference signal, and a clock signal, and on a clock transition (e.g., low to high transition), compares the input signal to the reference signal, with the comparator output then transitioning to a state corresponding to, and thereby indicating, whether the input signal exceeds the reference signal. Such devices are functionally and successfully implemented in numerous electronic circuits, but sometimes additional constraints based on the implementation cause a conventional approach to be insufficient for the application. The preferred embodiments, therefore, provide an improved clock comparator, for certain of such applications. For example and as better appreciated below, certain converters, such as DC-DC converters, may require ultra low (e.g., nano amps) power consumption in the device converter controller. The preferred embodiments are beneficial in this and other applications.

By way of further introduction, FIG. 1 illustrates a schematic of a prior art clocked comparator 10. In general, comparator 10 includes a symmetric left and right side of transistors that receive respective inputs Vin and Vref and, in response to a clock signal clk, couple signals to a latch stage 12.

Looking first along the left side of the comparator 10, a node 14 receives a positive supply voltage (Vdd) and is connected to the source of a pMOS transistor MP₁₃ and to the source of a pMOS transistor MP₁₂. The gate of pMOS transistor MP₁₃ is connected to receive the clock signal clk, and the drain of pMOS transistor MP₁₃ is connected to a node 16. The gate of pMOS transistor MP₁₂ is connected to a node 18, which is also connected to a gate of an nMOS transistor MN₁₂. The drain of pMOS transistor MP₁₂ and the drain of pMOS transistor MP₁₃ are both connected to node 16, which is further connected to the drain of nMOS transistor MN12. The source of nMOS transistor MN₁₂ is connected to the drain of an nMOS transistor MN₁₃, which has its gate connected to receive an input signal Vin and its source connected to a node 20.

Looking next along the right side of the comparator 10, node 14 is further connected to the source of a pMOS transistor MP₃₁ and to the source of a pMOS transistor MP₂₁. The gate of pMOS transistor MP₃₁ is connected to receive the clock signal clk, and the drain of pMOS transistor MP₃₁ is connected to node 18. The gate of pMOS transistor MP₂₁ is connected to node 16, which is also connected to a gate of an nMOS transistor MN₂₁. The drain of pMOS transistor MP₂₁ and the drain of pMOS transistor MP₃₁ are both connected to node 18, which is further connected to the drain of nMOS transistor MN₂₁. The source of nMOS transistor MN₂₁ is connected to the drain of an nMOS transistor MN₃₁, which has its gate connected to receive a reference signal Vref, where for certain applications Vref=Vdd. Lastly, the source of nMOS transistor MN₃₁ is connected to node 20.

Completing the connectivity of FIG. 1, node 20 is connected to a drain of an nMOS transistor MN₀, which has its gate connected to receive the clock signal clk and its source connected to ground. Nodes 16 and 18 provide inputs, respectively shown as S# and R#, to latch stage 12. Node 16 provides a first input to a NAND gate 22, and node 18 provides a first input to a NAND gate 24. The output of NAND gate 22, shown as Q, is connected to a second input of NAND gate 24, and the output of NAND gate 24, shown as Q#, is connected to a second input of NAND gate 22. In general, latch 12 operates as is well known in the art for an S-R latch. More particularly, therefore, the output states are complementary, indicated by the use of the “#” representation in Q#, which therefore is complementary to Q. In addition, when during a clock rising transition latch 12 receives a high signal at its set input (i.e., S#, the complement of S, equal to 0), the latch output of Q is set to high (i.e., Q=1), whereas when during a clock rising transition latch 12 receives a high signal at its reset input (i.e., R#, the complement of R, equal to 0), the latch output of Q is reset to low (i.e., Q=0). Moreover, the output state is retained until a next successive rising clock transition.

The above operation of latch 12 is controlled in connection with the remaining devices of comparator 10, through what may be referred to as a precharge phase and a regeneration phase, as now further discussed in connection with FIG. 2. Specifically, FIG. 2 illustrates a timing diagram with time across the horizontal and voltage across each vertical, with the bottom waveform illustrating the clock signal clk, the middle signal providing an example of the R# signal, and the top signal providing an example of the S# signal. Moreover, the precharge phase is shown when the signal clk is low (i.e., between times t₀ and t₁, and between times t₂ and t₃), and the regeneration phase when the signal clk is high (i.e., between times t₁ and t₂, and between times t₃ and t₄). The meaning of the phase descriptors and additional operational aspects are described below

At time t₀, the signal clk transitions low and begins the precharge phase, thereby enabling pMOS transistors MP₁₃ and MP₃₁ and conducting Vdd to nodes 16 and 18. For discussion in this document, the value of Vdd is likewise referred to as a logical 1, and the value of ground is referred to as logical 0. Thus, in the precharge phase, both nodes 16 and 18, and hence the respective signals S# and R# at those nodes, charge to a logical value of 1 (or Vdd, which in the present example equals 1.2 volts). The values at nodes 16 and 18 respectively enable nMOS transistors MN₂₁ and MN₁₂ and, therefore, further charge the respective source of each of those transistors to the respective voltage (Vdd) at the gate of each transistor, minus the threshold voltage, V_{T}, of each respective transistor, because during this phase there is no discharge path for either transistor to ground because nMOS transistor MN₀ is off in response to the low clk at its gate. Moreover, in latch 12, the logical value of 1 at nodes 16 and 18 provides respective first inputs to each of NAND gates 22 and 24. Note, however, that due to the cross coupling of the output with the second input of both such NAND gates, the previous complementary NAND gate outputs of Q and Q# will remain unaffected, as one of those outputs was a logical 0 and was cross-connected to the second input of the other NAND gate, thereby ensuring the output of that other NAND gates remains a logical 1.

At time t₁, the signal clk transitions high and begins the regeneration phase, thereby causing pMOS transistors MP₁₃ and MP₃₁ to turn off. As shown by way of example starting at time t₁, if Vref>Vin, then node 18 (i.e., R#) is discharged through the path of MN₂₁ (enabled by the 1 at node 16), MN₃₁ (enabled because Vref>Vin), and MN₀ (enabled by clk going high), while at the same time the discharge of node 18 enables pMOS transistor MP₁₂ to maintain node 16 at a logical 1, and the 0 at node 18 also disables nMOS transistor MN₁₂. In opposite fashion and as shown by way of example starting at time t₃, if Vin>Vref, then node 16 (i.e., S#) is discharged through the path of MN₁₂ (enabled by the 1 at node 18), MN₁₃ (enabled because Vin>Vref), and MN₀ (enabled by clk going high), while at the same time the discharge of node 16 enables pMOS transistor MP₂₁ to maintain node 18 at a logical 1, and the low at node 16 also disables nMOS transistor MN₂₁.

While the above operations are acceptable in various applications, FIG. 2 also illustrates two transitional dips TD₁ and TD₂, highlighted by way of dashed ovals, and in the respective signal waveforms for S# and R#. Specifically, at time t₃, where recall Vin>Vref, then in addition to the beginning of the steady discharge path of node 16 and S#, there is a short period of time where a discharge path also is enabled for node 18 and R#, because for a short period nMOS transistor MN₃₁ is also enabled. Particularly, immediately prior to time t₃, both nodes 16 and 18 are precharged high, thereby enabling both nMOS transistors MN₁₂ and MN₂₁. At time t₃, the clock transitions high and enables nMOS transistor MN₀, so immediately both nodes 16 and 18 start discharging. For the example of Vin>Vref, nMOS transistor MN₁₃ is more strongly (higher current drive) enabled than nMOS transistor MN₃₁, and, therefore node 16 discharges faster than node 18, but in any event, for a short period of time, both nodes 16 and 18 discharge, thereby creating the discharge portion of the transitional dip TD₂ following time t₃; however, an overlapping event during this time is that pMOS transistor MP₂₁ becomes enabled, by the proper discharge of node 16, so as to pull node 18 back to Vdd, thereby creating the return portion of the transitional dip TD₂ toward Vdd. Similarly, following time t₁, where recall Vref>Vin, then in addition to the beginning of the steady discharge path of node 18 and R#, there is a short period of time where a discharge path also may be enabled for node 16 and S# as nMOS transistor MN₁₃ is also enabled but less strongly than nMOS transistor MN₃₁, so again both nodes 16 and 18 may discharge, thereby creating the transitional dip TD₁ following time t₁, before pMOS transistor MP₁₂ is enabled, by the proper discharge of node 18, so as to pull node 16 back to Vdd. Such transitional dips, however, represent a period of time of unanticipated inputs to latch stage 12 and, therefore, can affect output performance, particularly if the dip swings far enough to cause a change in the latch output.

In addition to the preceding, the present inventors have observed additional drawbacks of the prior art.

For example, the possibility of mismatch between input nMOS transistors MN₁₃ and MN₃₁ also may affect the respective differential operation as between their inputs, that is, the mismatch creates a potential offset as between these inputs. As a result, and because Vin and Vref may be analog signals that are very close to one another, then a mismatch or offset between those two transistors may cause the wrong intended one of the two transistors to enable in a given operational cycle, thereby providing an invalid or erroneous input to the latch stage 12.

As another example, in various applications including that illustrated in FIG. 1, the reference voltage Vref is typically equal to Vdd. To ensure optimal detection of Vref>Vin by nMOS transistor MN₃₁ at the upward transition of the clk signal (or complementary detection of Vin>Vref by by nMOS transistor MN₁₃), however, it is desirable that the input transistor MN₃₁ (or MN₁₃) operates in saturation mode, that is, such that it is fully enabled by having its drain-to-source voltage (V_{DS}) exceeding its gate-to-source voltage (V_{GS}) minus its threshold voltage (V_{T}) (and V_{GS} exceeds V_{T}). Since Vref=Vdd=V_{GS}=1.2 volts, then for nMOS transistor MN₃₁ to be in saturation, its V_{DS} must at least meet or exceed 1.2−V_{T} during the regeneration phase. Note, however, that when the regeneration phase is occurring, the drain voltage applied to nMOS transistor MN₃₁ is provided from the source of nMOS transistor MN₂₁ (enabled by node 16); however, as node 18 begins to discharge even toward the beginning of the regeneration phase, the voltage at the transistor MN₂₁ source will decline. Thus, with the source of nMOS transistor MN₃₁ connected to ground by the enabled nMOS transistor MN0 during the regeneration phase, the declining drain voltage at nMOS transistor MN₃₁ can take it out of saturation mode, thereby inviting improper operation.

Certain alternative prior art approaches have attempted to address some of the above drawbacks. For example, one approach attempts to correct offset bias in the differential input transistor pair by applying a DC current source, switching AC coupled inputs, and storing an offset across capacitors during the pre-charge phase. This approach, however, addresses only DC offset and not dynamic offset due to node capacitance mismatch. In addition, the approach requires a DC current source which thereby increases power consumption in the microamp range, whereas certain applications are in need of an approach for considerably lower power (e.g., nanoamps). Another approach implements programmable capacitors on the input transistor pair drain nodes. However, this approach necessarily increases node capacitance, thereby requiring a higher dynamic power (as a linear function) consumption in operation. Still another approach implements a separate body bias to the nMOS devices so as to adjust the device behavior. In certain applications, however, this option is not viable as the nMOS body (or bulk) is necessarily tied to a fixed V_{SS} voltage, which typically is ground. Still another approach uses multiple stages, which again require greater power consumption.

Given the preceding, the present inventors have identified improvements to the prior art, as are further detailed below.

### BRIEF SUMMARY OF THE INVENTION

In a preferred embodiment, there is a comparator circuit comprising a first node operable to receive a voltage during a precharge phase and a second node operable to receive the voltage during the precharge phase. The comparator circuit also comprises a first selectable current path, comprising a first input transistor and a first programmable resistor, coupled to the first node and for selectively discharging the first node, and a second selectable current path, comprising a second input transistor and a second programmable resistor, coupled to the second node and for selectively discharging the second node, in complementary operation with respect to the first selectable current path. The comparator circuit also comprises circuitry for adjusting resistance of the first programmable resistor and the second programmable resistor in response to an offset between the first input transistor and the second input transistor.

Numerous other inventive aspects and preferred embodiments are also disclosed and claimed.

### BRIEF DESCRIPTION OF THE SEVERAL VIEWS OF THE DRAWING

FIG. 1 illustrates a schematic of a prior art clocked comparator.

FIG. 2 illustrates a timing diagram of the operation of the prior art clocked comparator of FIG. 1.

FIG. 3 illustrates a schematic of a preferred embodiment clocked comparator.

FIG. 4 illustrates a timing diagram of the clk, R# signal, and S# signal of the preferred embodiment, with reduced transitional dips at the beginning of the regeneration phases.

FIG. 5 illustrates a timing diagram of the clk and a comparison of the drain-to-source potential for the regeneration phase at the input differential transistors for the prior art and the preferred embodiment.

FIG. 6 illustrates a timing diagram of the clk and a comparison of the drain potential coupled to the drains of the input differential transistors, resulting from the precharge phase, for the prior art and the preferred embodiment.

FIG. 7 illustrates a DC-DC power converter, as an example of an improved system incorporating the preferred embodiment comparator.

### DETAILED DESCRIPTION OF EMBODIMENTS

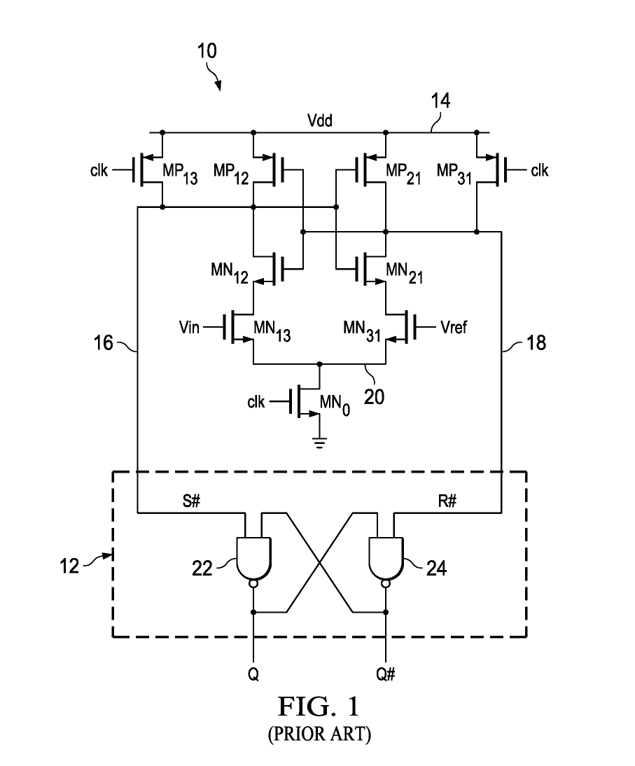

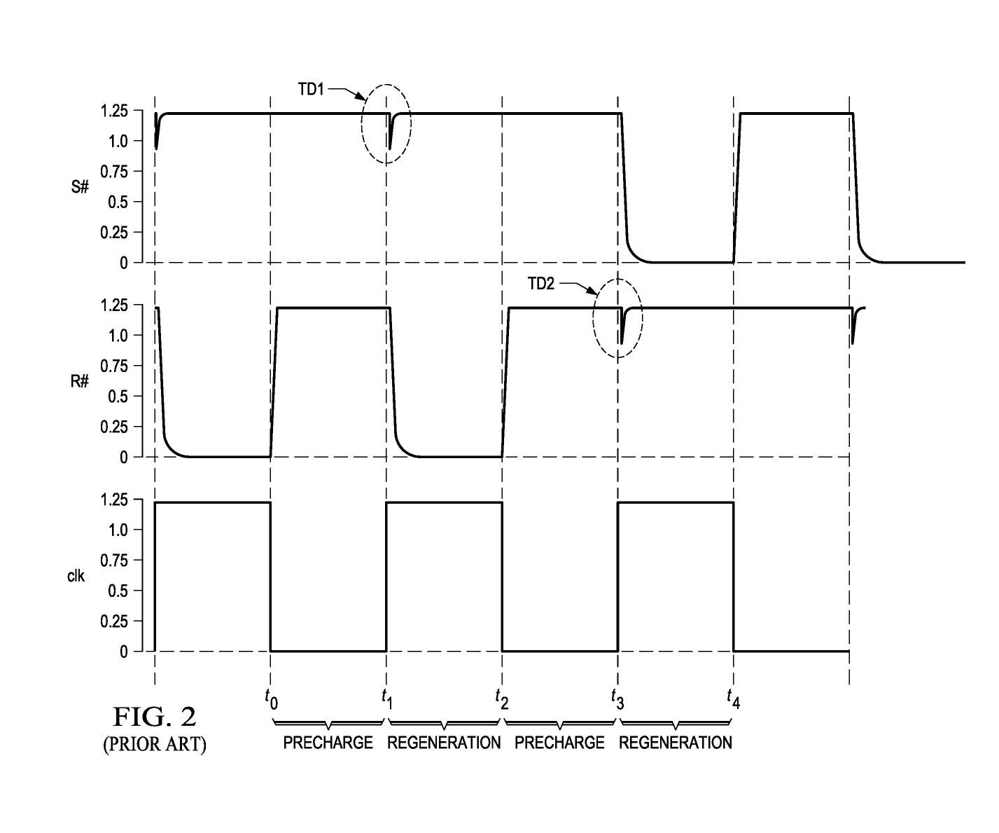

FIGS. 1 and 2 were described in the above Background Of The Invention section of this document, and the reader is assumed familiar with that discussion.

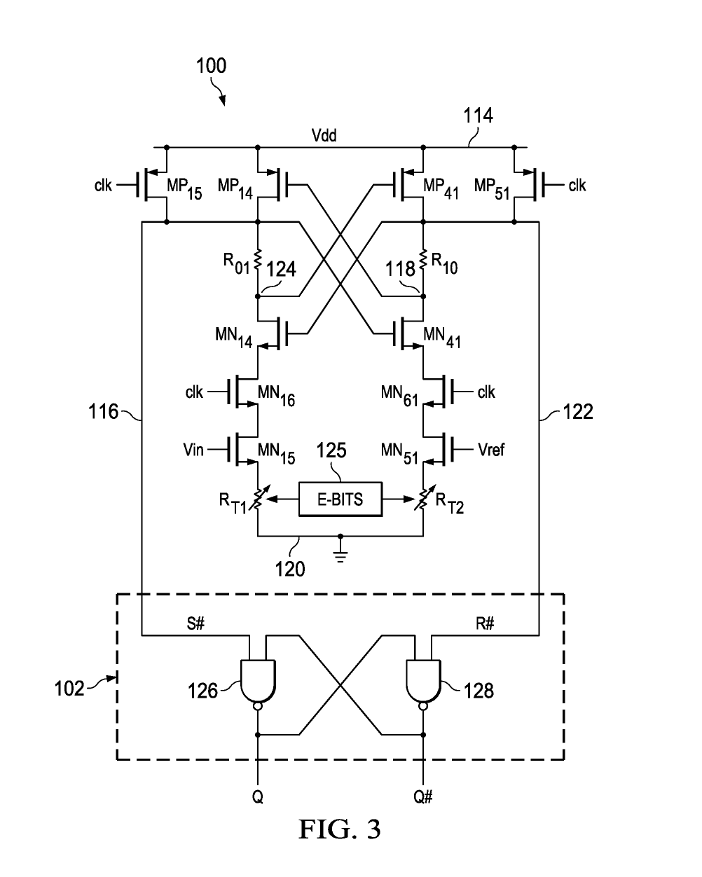

FIG. 3 illustrates a schematic of a preferred embodiment clocked comparator 100. In general, comparator 100 includes a symmetric left and right side of transistors that receive respective inputs Vin and Vref and, in response to a clock signal clk, couple signals to a latch stage 102.

Looking first along the left side of comparator 100, a node 114 receives a positive supply voltage (Vdd) and is connected to the source of a pMOS transistor MP₁₅ and to the source of a pMOS transistor MP₁₄. The gate of pMOS transistor MP₁₅ is connected to receive the clock signal clk, and the drain of pMOS transistor MP₁₅ is connected to a node 116. The gate of pMOS transistor MP₁₄ is connected to a node 118. The drain of pMOS transistor MP₁₄ and the drain of pMOS transistor MP₁₅ are both connected to node 116, which is further connected to a first terminal of a resistor R₀₁. The second terminal of resistor R₀₁ is connected to the drain of an nMOS transistor MN₁₄. Note also that in one preferred embodiment resistor R₀₁ is a resistive element, but in an alternative preferred embodiment, a resistance for resistor R₀₁ may be realized with a transistor. The source of nMOS transistor MN₁₄ is connected to the drain of an nMOS transistor MN₁₆, which has its gate connected to receive the clock signal clk and its source connected to the drain of an nMOS transistor MN₁₅, which has its gate connected to receive an input signal Vin and its source connected to a first terminal of a variable resistor R_{T1}. The second terminal of variable resistor R_{T1} is connected to a node 120. The resistance of variable resistor R_{T1} is selectable, programmable, or otherwise adjustable after the comparator is manufactured, and in the preferred embodiment this is accomplished by way of digital enabling bits shown in FIG. 3 as E-bits 125, as further discussed later.

Looking next along the right side of the comparator 100, node 114 is also connected to the source of a pMOS transistor MP₅₁ and to the source of a pMOS transistor MP₄₁. The gate of pMOS transistor MP₅₁ is connected to receive the clock signal clk, and the drain of pMOS transistor MP₄₁ is connected to a node 122. The gate of pMOS transistor MP₄₁ is connected to a node 124. The drain of pMOS transistor MP₄₁ and the drain of pMOS transistor MP₅₁ are both connected to node 122, which is further connected to a first terminal of a resistor R₁₀ (which, like resistor R₀₁, may be either a resistive element or realized with a transistor). The second terminal of resistor R₁₀ is connected to the drain of an nMOS transistor MN₄₁. The source of nMOS transistor MN₄₁ is connected to the drain of an nMOS transistor MN₆₁, which has its gate connected to receive the clock signal clk and its source connected to the drain of an nMOS transistor MN₅₁, which has its gate connected to receive an input signal Vref, where typically Vref=Vdd. Thus, as appreciated by one skilled in the art and particularly in view of the remaining discussion, nMOS transistor MN₅₁ and nMOS transistor MN₁₅ form a differential input stage to comparator 100. The source of nMOS transistor MN₅₁ is connected to a first terminal of a variable resistor R_{T2}, which also has an after-manufacture selectable or programmable resistance as indicated by digital enabling bits from E-bits 125. The second terminal of variable resistor R₁₇ is connected to node 120, where node 120 is connected to a discharge reference potential (e.g., ground).

Completing the connectivity of FIG. 3, nodes 116 and 122 provide inputs, respectively shown as S# and R#, to latch stage 102. Node 116 provides a first input to a NAND gate 126, and node 122 provides a first input to a NAND gate 128. The output of NAND gate 126, shown as Q, is connected to a second input of NAND gate 128, and the output of NAND gate 128, shown as Q#, is connected to a second input of NAND gate 126. In general, latch 102 operates as is well known in the art for an S-R latch and as descried earlier. Thus, the output states are complementary and when during a clock rising transition latch 102 receives a high signal at its set input (i.e., S#, the complement of S, equal to 0), the latch output of Q goes high (i.e., Q=1), whereas when during a clock rising transition latch 102 receives a high signal at its reset input (i.e., R#, the complement of R, equal to 0), the latch output of Q is reset to low (i.e., Q=0). Moreover, the output state is retained until a next successive rising clock transition.

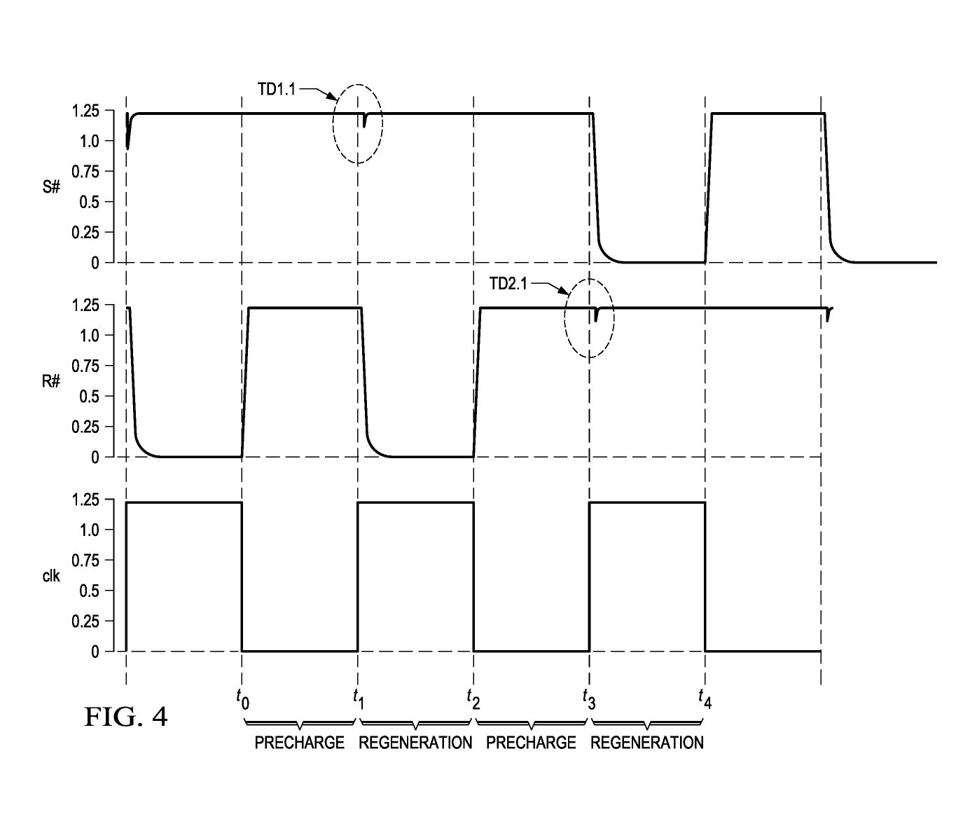

The operation of comparator 100 is now described, and in certain respects is comparable to comparator 10 of FIG. 1; comparator 100, however, includes additional circuitry and eliminates nMOS transistor MN₀ of FIG. 1, so as to achieve various preferred embodiment improvements. In this regard, comparator 100 also operates in both a precharge phase and a regeneration phase, as now further discussed in connection with FIG. 4. Specifically, FIG. 4 illustrates a timing diagram with time across the horizontal and voltage across each vertical, with the bottom waveform illustrating the clock signal clk, the middle signal providing an example of the R# signal, and the top signal providing an example of the S# signal. Again, the precharge phase is shown when the signal clk is low (i.e., between times t₀ and t₁, and between times t₂ and t₃), and the regeneration phase when the signal clk is high (i.e., between times t₁ and t₂, and between times t₃ and t₄). Additional aspects and benefits are described below.

At time t₀, the signal clk transitions low and begins the precharge phase, thereby enabling pMOS transistors MP₁₅ and MP₅₁, which thereby operate as a precharge stage and conduct Vdd to nodes 116 and 122. For discussion in this document, the value of Vdd is likewise referred to as a logical 1, and the value of ground is referred to as logical 0. Thus, in the precharge phase, both nodes 116 and 122, and hence the respective signals S# and R# at those nodes, charge to a logical value of 1 (or Vdd, which in the present example equals 1.2 volts). The values at nodes 116 and 122 respectively enable nMOS transistors MN₄₁ and MN₁₄ to further charge the sources of those transistors to the respective gate voltages at nMOS transistors MN₄₁ and MN₁₄, minus the threshold voltage, V_{T}, of the transistors, because during this phase there is no discharge path for either transistor to ground because each of nMOS transistors MN₁₆ and MN₆₁ are off, with a non-enabling low clk signal at their gates. Moreover, in latch 102, the logical value of 1 at nodes 116 and 122 provides respective first inputs to each of NAND gates 126 and 128. Note, however, that due to the cross coupling of the output with the second input of both such gates, the previous complementary NAND gate outputs of Q and Q# will remain unaffected, as one of those outputs was a logical 0 and was cross-connected to the second input of the other NAND gate, thereby ensuring the output of that other NAND gates remains a logical 1.

At time t₁, the signal clk transitions high and begins the regeneration phase, thereby causing pMOS transistors MP₁₅ and MP₅₁ to turn off and nMOS transistors MN₁₆ and MN₆₁ to turn on. As shown by way of example starting at time t₁, if Vref>Vin, then node 122 (i.e., R#) is discharged faster through the path of resistor R₁₀, transistor MN₄₁ (enabled by the 1 at node 116), transistor MN₁₆ (enabled by the high clk), transistor MN₅₁ (enabled more than MN₁₅, because Vref>Vin), and variable resistor R_{T2} to ground. Also during this same time following time t₁, then node 116 (i.e., S#) begins to discharge, slower than node 122, but through the path of resistor R₀₁, transistor MN₁₄ (enabled by the initial value of 1 at node 122), transistor MN₁₆ (enabled by the high clk), and transistor MN₁₅ (enabled less than MN₅₁ because Vref>Vin). In opposite fashion and as shown by way of example starting at time t₃, if Vin>Vref, then node 116 (i.e., S#) is discharged faster through the path of resistor R₀₁, transistor MN₁₄ (enabled by the 1 at node 122), transistor MN₆₁ (enabled by the high clk), transistor MN₁₅ (enabled but more than MN₅₁, because Vin>Vref), and variable resistor R_{D} to ground. Also during this same time following time t₃, then node 122 (i.e., R#) begins to discharge, slower than node 116, but through the path of resistor R₁₀, transistor MN₄₁ (enabled by the initial value of 1 at node 116), transistor MN₆₁ (enabled by the high clk), and transistor MN₅₁ (enabled less than MN₁₅ because Vinf>Vref).

The preceding demonstrates that comparator 100 includes two precharge nodes (i.e., nodes 116 and 122), and complementary selectable discharge paths so that during the regeneration phase one of those two nodes is selectably discharged, based in part in response to the relative magnitudes of the signals provided to the input stage nMOS transistors MN₁₅ and MN₅₁, which are respectively coupled to the precharge nodes through conductive paths that include additional transistors (and preferably resistors R₀₁ and R₁₀ as well). In either event (i.e., t₁ or t₃), complementary inputs are thus provided to latch 102, which will either set or reset the latch outputs Q and Q#, as is known in the art, and thereafter those latch outputs will be sustained during the regeneration phase and also during the subsequent precharge phase, after which they may again be switched, depending on the complementary values of S# and R# received in the next successive regeneration phase, and for additional successive such phases.

FIG. 4 also illustrates that the above transition from precharge phase to regeneration phase may give rise to two transitional dips TD_{1.1} and TD_{2.1}, highlighted by way of dashed ovals in the respective signal waveforms for S# and R#; importantly, however, the magnitude of such dips TD₁ and TD₂, shown in FIG. 2 are reduced relative to the prior art. The amount of reduction is due to the increased voltage at each of nodes 116 and 122, due to the inclusion of resistors R₀₁ and R₁₀. Specifically, when a regeneration phase commences (e.g., at time t₁ or time t₃), (the amount of voltage reduction achieved at nodes 116 and 122 is equal to I*R, where I is the current through each respective resistor at the time of regeneration and R is the resistance of resistors R₀₁ and R₁₀.

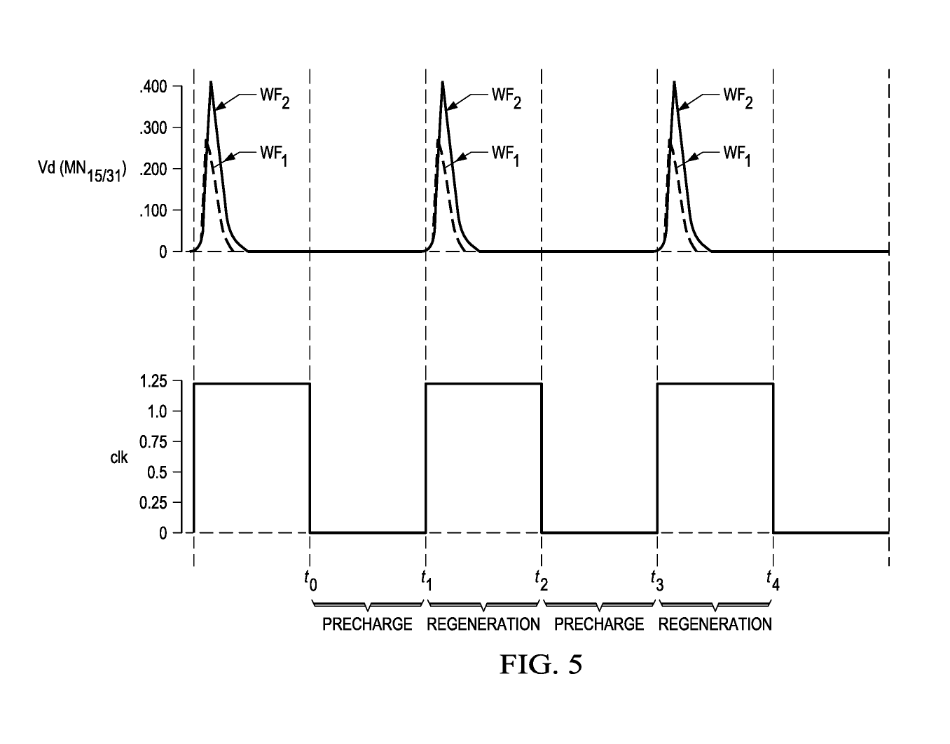

In the preferred embodiment, resistors R₀₁ and R₁₀ also provide the benefit of effectively increasing the V_{DS} across each of the differential input nMOS transistors MN₁₅ and MN₅₁ during the regeneration phase, as further illustrated in FIG. 5. Prior to examining FIG. 5, recall from above that the inclusion of resistors R₀₁ and R₁₀ creates a respective voltage across each resistor in response to the current through it, thereby providing that voltage to nodes 116 and 122; each of those node voltages is respectively coupled to a gate of nMOS transistors MN₄₁ and MN₁₄, so the source of each of those transistors MN₄₁ and MN₁₄ is at the transistor gate voltage (increased by one of resistors R₀₁ and R₁₀) minus the V_{T} of that transistor—further, each of these transistor MN₄₁ and MN₁₄ source voltages is respectively coupled to a drain of nMOS transistors MN₅₁ and MN₁₅ (via nMOS transistors MN₆₁ and MN₁₆, when clk rises), so the increased voltage of I*R through resistors R₀₁ and R₁₀ corresponds to a relative increase in the drain voltages of nMOS transistors MN₅₁ and MN₁₅. This increase is confirmed in FIG. 5, which again illustrates time along a horizontal axis and voltage along the vertical axis of each of the illustrated waveforms. The bottom waveform is again the clk signal and precharge and regeneration phases introduced above. At the top of the Figure, a first waveform WF₁, shown in dashed lines, illustrates the drain voltage at whichever of the preferred embodiment input differential nMOS transistors MN₁₅ and MN₅₁ is enabled, and without (replaced with a short) resistor R₀₁ or resistor R₁₀ in the path (i.e., based on the comparative values of Vref and Vin), while a second waveform WF₂, shown in a solid line, illustrates the drain voltage at whichever of the preferred embodiment input differential nMOS transistors MN₁₅ and MN₅₁ is enabled. Notably, therefore, the preferred embodiment increases the regeneration phase drain voltage of the input differential nMOS transistors MN₁₅ and MN₅₁, as compared to the counterpart prior art without (replaced with a short) resistors R₀₁ and R₁₀ in the path. This increase better ensures that each of the input differential nMOS transistors MN₁₅ and MN₅₁ operates in saturation mode.

From the preceding, one skilled in the art will appreciate that the preferred embodiment resistors R₀₁ and R₁₀ provide benefits in connection with reducing transitional dips as well as increasing the V_{DS} across each of the differential input nMOS transistors MN₁₅ and MN₅₁ during the regeneration phase. The values of these resistors, therefore, are preferably selected in consideration of both of these functions and benefits. Specifically, increasing the resistance value of resistors R₀₁ and R₁₀ improves the V_{DS} (headroom) for nMOS transistor MN_{15/51} and reduces transitional dip. However, it is to be noted that the maximum value of these resistor is limited by the amount of discharge required on nodes 116 and 122, namely, in the regeneration phase (i.e., clk transition low to high), node 116 and 122 should start discharging before pMOS transistors MP₁₄ and MP₄₁ are enabled (i.e., before nodes 124 and 118 go below Vdd minus V_{T} of pMOS transistors MP₁₄ and MP₄₁). Knowing that, at the onset of the regeneration phase, nodes 116 and 122 are at Vdd, the preferred maximum resistance value of resistors R₀₁ and R₁₀ can be estimated using the inequality I*R<V_{T}, where I is the current through resistors R₀₁ and R₁₀ in the regeneration phase, R is resistor value (of either of resistors R₀₁ and R₁₀), and V_{T} is the threshold voltage of each of pMOS transistors MP₁₄ and MP₄₁.

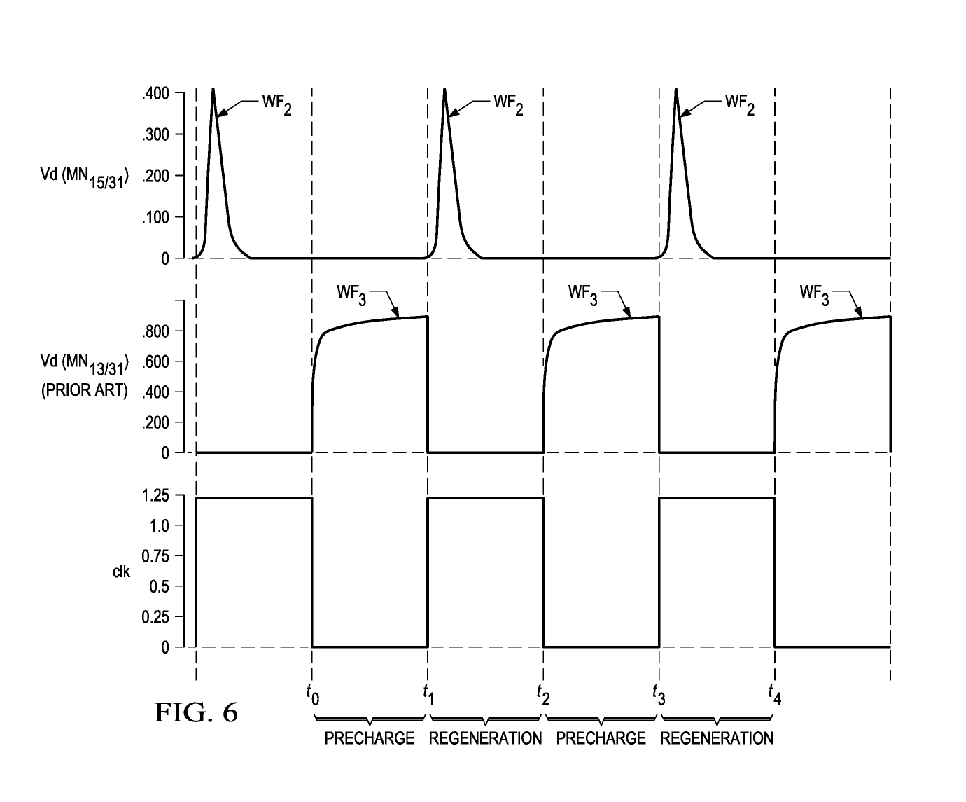

Additional observations are now made with respect to nMOS transistors MN₁₆ and MN₆₁. Recall from above that these transistors are off during the precharge phase, while nMOS transistors MN₁₄ and MN₄₁ provide a precharge voltage. Thus, whereas the prior art of FIG. 1 couples the precharge voltage to the drains of the differential input pair MN₁₃ and MN₃₁ during the entire precharge phase, the preferred embodiment only couples the precharge voltage at the instant or in response to the clk transition (e.g., from low to high) between the end of the precharge phase and the beginning of the regeneration phase. To further demonstrate this, FIG. 6 illustrates a comparison of the prior art and preferred embodiment signal waveforms at the drains of the differential input pair (i.e., nMOS transistors MN₁₃₁₃₁ in the prior art; MN_{15/51} in the preferred embodiment). Specifically, FIG. 6 again illustrates time along a horizontal axis and voltage along the vertical axis of each of the illustrated waveforms. The bottom waveform is again the clk signal and precharge and regeneration phases introduced above. At the middle of FIG. 6, a waveform WF₃ is shown, and it illustrates the drain voltage at whichever of the FIG. 1 prior art input differential nMOS transistors MN₁₃ and MN₃₁ is enabled (i.e., based on the comparative values of Vref and Vin), while the top waveform in FIG. 6 is again waveform WF₂ shown in, and repeated from, FIG. 5, which recall illustrates the drain voltage at whichever of the preferred embodiment input differential nMOS transistors MN₁₅ and MN₅₁ is enabled. As can be seen in waveform WF₃ of the prior art, during the entirety of the precharge phase, a non-zero and rising voltage is applied to the drain of nMOS transistors MN₁₃/MN₃₁, reaching a maximum of approximately 0.800 volts at the end of the precharge phase; thereafter, the signal clk transitions up (which can discharge the potential, assuming the transistor to which drain node is receiving the voltage is enabled). At this instant, however, due to the drain-to-gate capacitance of nMOS transistors MN₁₃/MN₃₁, some of the drain potential is coupled to the receptive gate potential, which therefore can affect the proper or intended switching functionality of the transistor, as the coupled voltage is further input as part of the gate signal to the device. In contrast, however, consider waveform WF₂ of the preferred embodiment. Due to the presence of nMOS transistors MN₁₆ and MN₆₁, the voltage at nodes 116 and 122 during the precharge phase is not transferred during that time to the drains of the input differential pair nMOS transistors MN₁₅ and MN₅₁; instead, only at the rising transition of clk do nMOS transistors MN₁₆ and MN₆₁ begin to pass the node 116/122 voltage to the drains of the input differential pair nMOS transistors MN₁₅ and MN₅₁, while at the same time those latter devices are able to more properly operate (i.e., either turn on or remain off) in response to their gate signals. This improved operation is demonstrated in that waveform WF₂ is shown to reach a lesser magnitude at the clk rising transition (e.g., approximately 0.400 volts), as compared to the prior art waveform WF₃.

Recall that comparator 100 also includes variable resistors R_{T1} and R_{T2}, having selectable resistance, controlled for example by E-bits 125. As known in the art, e-bits represent a group of connections that may be one time programmed or selected, such as at testing of the device after manufacture, whereby some connections are opened (e.g., by blowing a respective fuse) to create a respective open circuit while others are left intact to provide a respective conductive path. In any event, in the preferred embodiment, therefore, through testing, the input DC offset of the left and right conductive paths, respectively, through nMOS transistor MN₁₅ and MN₅₁ is measured, and then E-bits 125 are set so as to adjust variable resistors R_{T1} and R_{T2} to correct for the measured offset. For example, based on the input offset magnitude and sign, resistance may be increased to the source of either nMOS transistor MN₁₅ and MN₅₁, so as to resist current through the respective transistor, thereby offsetting for a potential mismatch wherein that transistor is stronger (i.e., larger source of current when enabled) relative to the opposing input stage transistor.

In an additional preferred embodiment, variable resistors R_{T1} and R_{T2} either additionally, or alternatively, also represent resistance that may be selectable based on the prior state of Q and Q#, that is, to produce input hysteresis effect whereby an offset is created in the conductive paths of nMOS transistor MN₁₅ and MN₅₁ based on the prior history of outputs, that is, as represented by Q and Q#. In this regard, in addition to E-bits 125, additional (e.g., combinational) logic is provided so as to selectively enable resistance (as indicated by variable resistors R_{T1} and R_{T2}) in response to the immediately prior state of Q and Q#. Given the preceding, a hysteresis adjustment feature is added to comparator 100 to improve its input noise immunity, where the amount of hysteresis is set based on amplitude of noise to be rejected. For example, for an amplitude of +/−15 mV noise to be rejected, turn-on R, such that I*R=15 mV, on right side for Q=1 and on left side for Q=0. Such an adjustment should be large enough to reject the noise but should be small enough to ensure proper detection of input signal.

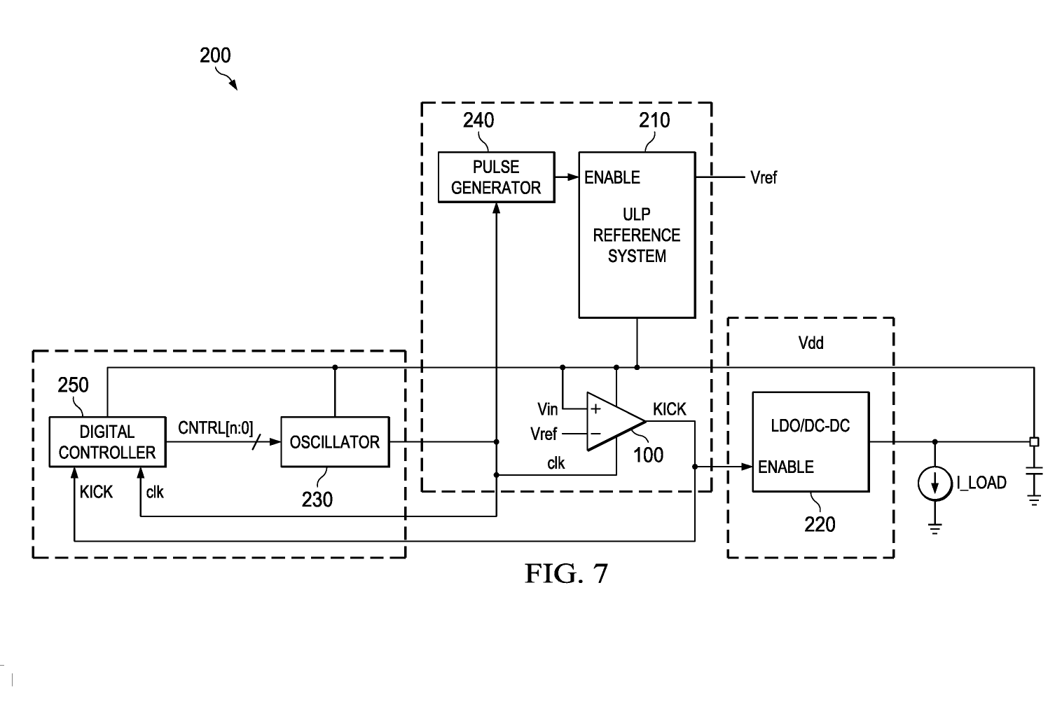

FIG. 7 illustrates a DC-DC power converter 200, as an example of an improved system incorporating the preferred embodiment comparator 100 described above. Comparator 100 can be seen again to receive a reference input Vref and an input signal Vin, where Vref is provided by an ultra low power (ULP) reference system 210, and Vin is the output of a low drop out (LDO) DC-DC converter block 220. Moreover, comparator 100 receives its clk signal from an oscillator 230, where the clk signal from oscillator 230 also is input to a pulse generator 240, which provides an Enable signal to ULP reference system 210. Oscillator 230 is controlled by a control signal CNTRL[n:0], provided by a digital controller 250. Digital controller 250 provides the control signal CNTRL[n:0] in response to the oscillator 230 clock signal clk and the output of comparator 100, which is referred to as a KICK signal. The kick signal also controls the Enable of LDO DC-DC converter block 220. Finally, LDO DC-DC converter block 220 outputs a regulated DC voltage Vdd, which provides a bias voltage to numerous of the blocks in FIG. 7, including comparator 100. In any event, the operation of converter 200 will be readily understood by one skilled in the art, and consistent with the earlier discussion, represents an instance where the DC voltage of Vdd (from block 220) is used both as the voltage supply Vdd and input voltage to the comparator 100.

From the above, various embodiments provide numerous improvements to clocked comparators and thereby includes various benefits over the prior art. Such benefits include zero consumption of static power and sub-nanowatt/KHz dynamic power consumption. Moreover, the comparator provides a wide input common mode up to Vdd and with improved differential input sensitivity. The comparator also provides reduced DC offset and noise correction through a hysteresis correction feature. Still further, the comparator includes reduced input stage drain coupling to the reference voltage (Vref). Yet still further, while one preferred embodiment implements comparator 100 into a DC-DC converter, related preferred embodiment devices also may incorporate the inventive comparator, as may be readily developed or ascertained by one skilled in the art. Various aspects have been described, and still others will be ascertainable by one skilled in the art from the present teachings. Given the preceding, therefore, one skilled in the art should further appreciate that while some embodiments have been described in detail, various substitutions, modifications or alterations can be made to the descriptions set forth above without departing from the inventive scope, as is defined by the following claims.

1. A comparator circuit, comprising:
a first output node operable to receive a voltage during a precharge phase;
a second output node operable to receive the voltage during the precharge phase;
a first selectable current path, comprising a first transistor coupled between a first supply voltage terminal and the first output node, a second transistor, a first resistor coupled between the first output node and the second transistor, and a first clock transistor connected in series with a first input transistor between the second transistor and a second supply voltage terminal for selectively discharging the first output node; and
a second selectable current path, comprising a third transistor coupled between the first supply voltage terminal and the second output node, a fourth transistor, a second resistor coupled between the second output node and the fourth transistor, and a second clock transistor connected in series with a second input transistor between the fourth transistor and the second supply voltage terminal for selectively discharging the second output node in complementary operation with respect to the first selectable current path.

2. The comparator circuit of claim 1, comprising:
a first programmable resistor coupled between the first input transistor and the second supply voltage terminal; and
a second programmable resistor coupled between the second input transistor and the second supply voltage terminal.

3. The comparator circuit of claim 1, wherein the second supply voltage terminal is ground.

4. The comparator circuit of claim 1:
wherein a control terminal of the first transistor is coupled to a junction of the second resistor and the fourth transistor; and
wherein a control terminal of the third transistor is coupled to a junction of the first resistor and the second transistor.

5. The comparator circuit of claim 1, wherein each of the first transistor and the third transistor comprises a pMOS transistor, and wherein each of the second transistor and the fourth transistor comprises an nMOS transistor.

6. The comparator circuit of claim 1, wherein each of the first and second clock transistors is disabled during the precharge phase and enabled during a regeneration phase.

7. The comparator circuit of claim 1,
wherein a control terminal of the second transistor is coupled to a junction of the second resistor and the third transistor; and
wherein a control terminal of the fourth transistor is coupled to a junction of the first resistor and the first transistor.

8. The comparator circuit of claim 2, comprising:
circuitry for adjusting resistance of the first programmable resistor and the second programmable resistor to correct a DC offset voltage of the comparator circuit.

9. The comparator circuit of claim 2, comprising
circuitry for adjusting resistance of the first programmable resistor and the second programmable to provide a hysteresis voltage of the comparator circuit to reject noise.

10. The comparator circuit of claim 1, comprising:
a first logic gate having a first input terminal coupled to the first output node and configured to produce a first output signal; and
a second logic gate having a first input terminal coupled to the second output node, a second input terminal coupled to receive the first output signal, and configured to produce a second output signal at a second input terminal of the first logic gate.

11-17. (canceled)

18. A comparator circuit, comprising:
a first transistor coupled between a first supply voltage terminal and a first output node;
a second transistor having a control terminal coupled to a second output node;
a first resistor coupled between the first output node and the second transistor;
a first input transistor having a control terminal coupled to receive an input voltage and having a current path coupled between the second transistor and a second supply voltage terminal;
a third transistor coupled between the first supply voltage terminal and the second output node;
a fourth transistor having a control terminal coupled to the first output node;
a second resistor coupled between the second output node and the fourth transistor; and
a second input transistor having a control terminal coupled to the first supply voltage terminal and having a current path coupled between the fourth transistor and the second supply voltage terminal.

19. The comparator circuit of claim 18, comprising:
a first clock transistor having a current path coupled in series with the first input transistor and having a control terminal coupled to receive a clock signal; and
a second clock transistor having a current path coupled in series with the second input transistor and having a control terminal coupled to receive the clock signal.

20. The comparator circuit of claim 18, comprising:
a first programmable resistor coupled between the first input transistor and the second supply voltage terminal; and
a second programmable resistor coupled between the second input transistor and the second supply voltage terminal.

21. The comparator circuit of claim 19, comprising circuitry for adjusting resistance of the first and second programmable resistors to correct a DC offset voltage of the comparator circuit.

22. The comparator circuit of claim 19, comprising circuitry for adjusting resistance of the first and second programmable resistors to provide a hysteresis voltage of the comparator circuit to reject noise.

23. The comparator circuit of claim 18, wherein a control terminal of the first transistor is coupled to a junction of the second resistor and the fourth transistor,
wherein a control terminal of the third transistor is coupled to a junction of the first resistor and the second transistor,
wherein a control terminal of the second transistor is coupled to a junction of the second resistor and the third transistor, and
wherein a control terminal of the fourth transistor is coupled to a junction of the first resistor and the first transistor.

24. A comparator circuit, comprising:
a first transistor coupled between a first supply voltage terminal and a first output node;
a second transistor having a control terminal coupled to a second output node;
a first resistor coupled between the first output node and the second transistor;
a first input transistor having a control terminal coupled to receive an input voltage and having a current path coupled between the second transistor and a second supply voltage terminal;
a third transistor coupled between the first supply voltage terminal and the second output node;
a fourth transistor having a control terminal coupled to the first output node;
a second resistor coupled between the second output node and the fourth transistor; and
a second input transistor having a control terminal coupled to receive a reference voltage and having a current path coupled between the fourth transistor and the second supply voltage terminal.

25. The comparator circuit of claim 24, wherein a maximum voltage across the first resistor is less than or equal to a threshold voltage of the third transistor, and wherein a maximum voltage across the second resistor is less than or equal to a threshold voltage of the first transistor.

26. The comparator circuit of claim 24, comprising:
a first programmable resistor coupled between the first input transistor and the second supply voltage terminal; and
a second programmable resistor coupled between the second input transistor and the second supply voltage terminal.

27. The comparator circuit of claim 24, comprising:
a first clock transistor having a current path coupled in series with the first input transistor and having a control terminal coupled to receive a clock signal; and
a second clock transistor having a current path coupled in series with the second input transistor and having a control terminal coupled to receive the clock signal.
